(19) United States
(12) Patent Application Publication
(10) Pub. No.: US 2017/0025291 A1
(43) Pub. Date: Jan. 26, 2017

(54) MULTI-CHAMBER FURNACE FOR BATCH PROCESSING

(71) Applicant: Taiwan Semiconductor Manufacturing Co., Ltd., Hsin-Chu (TW)

(72) Inventor: Su-Horng Lin, Hsinchu City (TW)

(21) Appl. No.: 14/805,584

(22) Filed: Jul. 22, 2015

(51) Int. Cl. H01L 21/67; C23C 16/458; F27B 5/02; H01L 21/66; H01L 21/687; H01L 21/677; H01L 21/02; H01L 21/324; C23C 16/455; F27B 5/12

(52) U.S. Cl. CPC H01L 21/67207; C23C 16/45544; C23C 16/4582; F27B 5/02; F27B 5/12; H01L 21/67098; H01L 21/68771; H01L 21/67751; H01L 21/67196; H01L 21/67742; H01L 21/67201; H01L 21/0223; H01L 21/324; H01L 22/20; H01L 21/67253; H01L 21/02255

(57) ABSTRACT

A multi-chamber furnace for processing at least 100 substrates is provided. Reactor housings define a plurality of laterally spaced reactor chambers that are individually configured to accommodate up to about 50 substrates. Substrate holders correspond to the reactor chambers, and are configured to support and vertically stack substrates arranged in the corresponding reactor chambers. Heaters correspond to the reactor chambers and are configured to heat the corresponding reactor chambers. A method for batch processing substrates using the multi-chamber furnace is also provided.

### BACKGROUND

Some semiconductor manufacturing processes are performed in a furnace, where one or more substrates, such as one or more wafers, are processed at an elevated temperature. The semiconductor manufacturing processes performed in a furnace include, for example, annealing and thermal oxidation. During annealing, atoms of the substrate(s) migrate in the crystal lattice and the number of dislocations decreases to the change ductility and hardness of the substrate(s). While the semiconductor manufacturing processes may be individually applied to substrates, the semiconductor manufacturing processes are commonly applied to batches of two or more substrates. This so called batch processing advantageously allows a batch of two or more substrates to undergo a semiconductor manufacturing process concurrently and therefore increases throughput and yield.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a top view of some embodiments of a multi-chamber furnace for batch processing.

FIG. 1B illustrates a cross-sectional view of some embodiments of the multi-chamber furnace of FIG. 1A.

FIG. 2A illustrates a top view of other embodiments of a multi-chamber furnace for batch processing.

FIG. 2B illustrates a cross-sectional view of some embodiments of a chamber of the multi-chamber furnace of FIG. 2A.

FIG. 3 illustrates a flowchart of some embodiments of a method for batch processing substrates in a multi-chamber furnace.

FIGS. 4, 5, 6A-E, and 7A-E illustrate a series of top and cross-sectional views for some embodiments of a multi-chamber furnace during performance of the method of FIG. 3.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some furnaces used to perform a semiconductor manufacturing process on a batch of substrates, such as wafers, comprise a reactor chamber accommodating a vertical stack of the substrates. The substrates are laterally surrounded by a first heater, and are supported over a second heater by a substrate holder that vertically spaces the substrates from one another. Gas sources outside the reactor chamber provide process gases to gas inlets of the reactor. Distribution lines arranged in the reactor chamber extend vertically from the gas inlets to distribute the process gases throughout the reactor chamber. An exhaust pump outside the reactor chamber is connected to an exhaust outlet of the reactor to remove gases from the reactor chamber.

A challenge with the above described furnaces is that the furnaces are typically designed for and applied to batches of 100 or more substrates. However, with such a large number of substrates, uniformly controlling parameters of the semiconductor manufacturing process, such as gas flow rate and/or temperature, across the substrates is challenging. As such, the semiconductor manufacturing process typically varies across the substrates. For example, the within batch (WiB) thickness profiles of deposited or otherwise grown layers may vary substantially and/or the WiB percentage of non-uniform substrates may be high. With semiconductor devices continuing to shrink, and margins around design specifications getting smaller, the percentage of non-uniform substrates is expected to increase.

Another challenge with the above described furnaces is that the cycle time for processing a single batch of substrates is higher than the minimum time for processing a single substrate from the batch. Namely, because the substrates are all processed together, and the semiconductor manufacturing process typically varies across the substrates, the WiB processing times of the substrates are non-uniform (i.e., some substrates take longer to process than others). Therefore, the cycle time is at least equal to the largest WiB processing time of the substrates. This, in turn, reduces throughput and the wafers per hour (WPH) that can be processed.

In view of the foregoing, the present application is directed to a multi-chamber furnace that processes a batch of about 100 or more substrates and that improves upon the foregoing challenges. In some embodiments, the multi-chamber furnace comprises a plurality of laterally spaced reactor chambers configured to accommodate respective subsets of the batch of substrates so as to collectively process the whole of the batch. The reactor chambers are individually configured to accommodate between about 25 to about 50 substrates, and no more than about 50 substrates. Substrate holders corresponding to the reactor chambers are arranged in the corresponding reactor chambers, and are configured to support and vertically space the substrates of the corresponding reactor chambers.

By distributing a batch of substrates amongst a plurality of reactor chambers, cycle time can advantageously be reduced (e.g., by about 65%) and the WPH can be increased. Further, by distributing a batch of substrates amongst a plurality of reactor chambers, parameters of a semiconductor manufacturing process can be more readily controlled across the substrates of a batch. This, in turn, may advantageously improve the WiB uniformity of the semiconductor manufacturing process. For example, the uniformity of WiB thickness profiles of deposited layers may be improved and/or the WiB percentage of non-uniform substrates may be reduced.

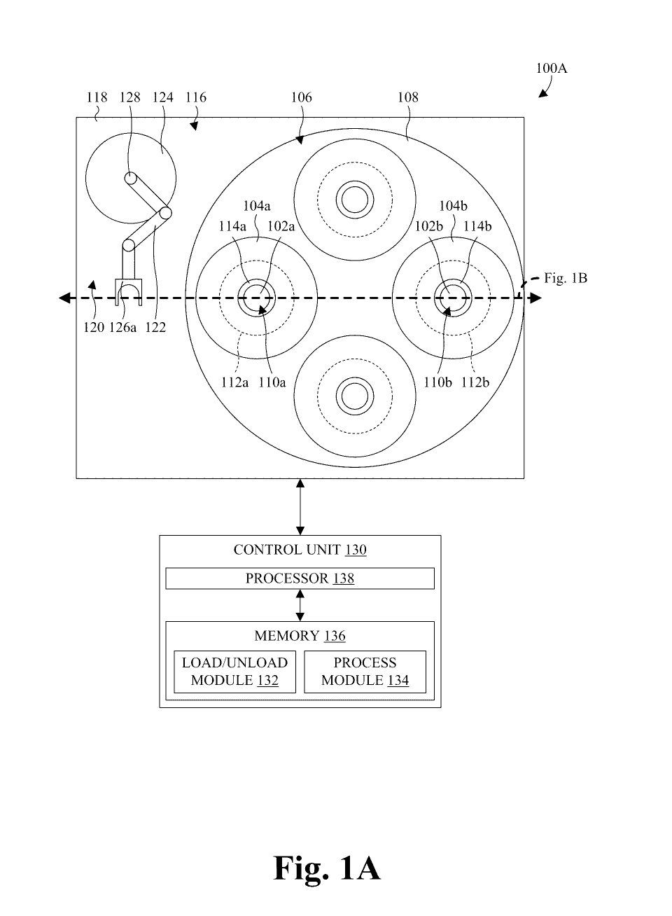

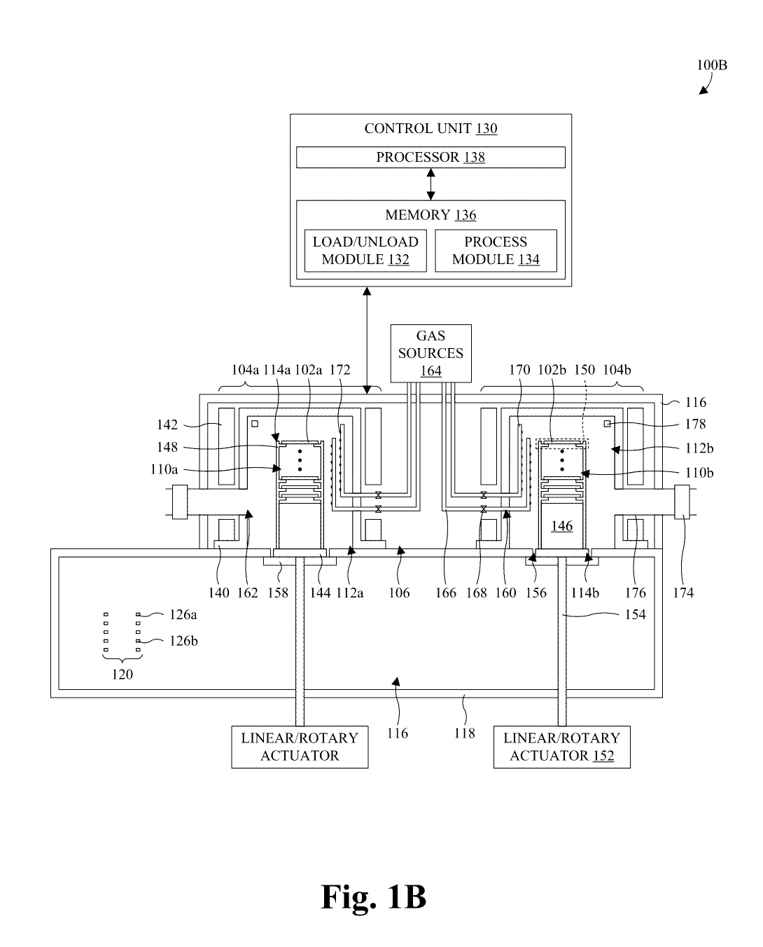

With reference to FIG. 1A, a top view 100 of some embodiments of a multi-chamber furnace is provided. The multi-chamber furnace is configured to process a batch of substrates 102a, 102b, such as a batch of wafers, according to a semiconductor manufacturing process dependent upon the application of heat to the substrates 102a, 102b. The wafers may be, for example, quartz, silicon carbide, or ceramic. Such semiconductor manufacturing processes may include, for example, a chemical reaction, such as thermal oxidation, and annealing. The batch typically includes about 100 or more substrates 102a, 102b. The multi-chamber furnace includes a plurality of reactors 104a, 104b, such as between about 2 to about 4 reactors (illustrated as 4 reactors).

The reactors 104a, 104b are laterally spaced from one another and arranged within a process area 106 defined by a process housing 108. The reactors 104a, 104b are configured to process corresponding subsets 110a, 110b of the batch (i.e., smaller batches of substrates 102a, 102b) according to the semiconductor manufacturing process so as to collectively process the whole of the batch. In some embodiments, the reactors 104a, 104b are individually configured to process between about 25 to about 50 substrates 102a, 102b of the batch, and no more than about 50 substrates 102a, 102b of the batch. Further, in some embodiments, the reactors 104a, 104b are individually configured to process the same number of substrates as stored by a pod (e.g., a front opening unified pod (FOUP)), or an integer multiple (e.g., 2) of the number of substrates stored by the pod. Even more, in some embodiments, the reactors 104a, 104b are configured to process the same number of substrates 102a, 102b.

Advantageously, distributing and processing the batch of substrates 102a, 102b amongst the plurality of reactors 104a, 104b, as opposed to processing the batch in a single large reactor, improves cycle time for processing the batch. Further, parameters of the semiconductor manufacturing process can advantageously be controlled more readily and uniformly across the substrates 102a, 102b of the batch since the reactors 104a, 104b are smaller. This, in turn, may advantageously improve the WiB uniformity of the semiconductor manufacturing process.

With continued reference to FIG. 1A, the reactors 104a, 104b include corresponding reactor chambers 112a, 112b and corresponding substrate holders 114a, 114b. The reactor chambers 112a, 112b are configured to provide a suitable environment for carrying the semiconductor manufacturing process. The substrate holders 114a, 114b are configured to vertically stack and space the substrates 102a, 102b of the corresponding reactors 104a, 104b. Further, the substrate holders 114a, 114b are configured to move vertically between the reactor chambers 112a, 112b and a loading area 116 under the reactors 104a, 104b so as to facilitate loading and unloading of the substrates 102a, 102b of the corresponding reactors 104a, 104b.

The loading area 116 is defined by a loading housing 118 arranged under the process housing 108 and the reactors 104a, 104b. The loading area 116 accommodates a robot 120 configured to place the substrates 102a, 102b of the batch in the substrate holders 114a, 114b and to pick the substrates 102a, 102b from the substrate holders 114a, 114b so as to facilitate loading and unloading of the batch. The robot 120 includes one or more rods 122 connected end to end between a motor 124 and a vertical stack of one or more blades 126a by bearings 128. In some embodiments, the rod(s) 122 telescope. The motor 124 is configured to vertically, horizontally, and/or rotationally move the blade(s) 126a along the bearings 128.

The blade(s) 126a respectively include one or more pairs of laterally spaced fingers, each pair typically configured to support a single substrate. In some embodiments, the blade(s) 126a are limited to a single blade configured to support a single substrate. In other embodiments, the blade(s) 126a include multiple blades, each comprising one or more pairs of laterally spaced fingers configured to support at least one substrate. In yet other embodiments, the blade(s) 126a include a single blade comprising multiple pairs of laterally spaced fingers configured to support a plurality of substrates. Advantageously, where the blade(s) 126a are configured to support multiple substrates, loading or unloading of the reactors 104a, 104b can be performed more quickly, thereby improving throughput.

A control unit 130 is electrically coupled with the reactors 104a, 104b and/or the robot 120, and configured to control the reactors 104a, 104b and/or the robot 120. For example, the control unit 130 may include a load/unload module 132 configured to control the robot 120 and/or the reactors 104a, 104b for loading and unloading substrates 102a, 102b to and from the substrate holders 114a, 114b. As another example, the control unit 130 may include a process module 134 configured to individually control the reactors 104a, 104b to carry out the semiconductor manufacturing process on the substrates 102a, 102b. Such individual control of the reactors 104a, 104b may include individual control of components of the reactors 104a, 104b in accordance with target values for parameters of the semiconductor manufacturing process, such as temperatures, process gas concentrations, and gas flow rates.

The control unit 130 is implemented by hardware and, in some embodiments, software configured to carry out the foregoing functionality. For example, the control unit 130 may include a field-programmable gate array (FPGA) or some other circuit. Further, to the extent that the control unit 130 includes software, the control unit 130 includes at least one memory 136 storing the software and at least one processor 138 configured to execute the software. For example, the control unit 130 may include a microcontroller, a microprocessor, or an application-specific integrated circuit (ASIC) configured to execute the software from the at least one memory 136. In some embodiments (as illustrated), the software include the load/unload module 132 and/or the process module 134.

With reference to FIG. 1B, a cross-sectional view 100B of some embodiments of the multi-chamber furnace is provided. The reactors 104a, 104b include corresponding reactor housings 140 defining the reactor chambers 112a, 112b, and include corresponding first heaters 142 surrounding the reactor chambers 112a, 112b outside the reactor chambers 112a, 112b. The first heaters 142 are arranged along sidewall surfaces of the reactor housings 140 and laterally surround the reactor chambers 112a, 112b. Further, in some embodiments, the first heaters 142 are arranged over and/or below the reactor housings 140. The first heaters 142 may be, for example, resistive heaters, in which large currents are passed over resistive heating elements to produce heat.

The substrate holders 114a, 114b include corresponding bases 144 supporting corresponding second heaters 146 and corresponding racks 148. The second heaters 146 may be, for example, resistive heaters. The racks 148 are configured to support and vertically space the substrates 102a, 102b of the corresponding subsets 110a, 110b over the second heaters 146 and to stack the substrates 102a, 102b. The racks 148 include corresponding pairs of vertical columns laterally spaced on opposing sides of the second heaters 146. Further, the racks 148 include corresponding pairs of ledges extending laterally from the vertical columns and vertically spaced along the substantial height of the vertical columns. The pairs of ledges, together with the corresponding regions of the vertical columns, define slots 150 for the substrates 102a, 102b, such as one slot for each substrate. While the slots 150 are typically fixed, in some embodiments, the slots 150 may be removable or otherwise moveable within the reactor chambers 112a, 112b. For example, the slots 150 may be loaded and unloaded with the substrates 102a, 102b.

Linear and/or rotary actuators 152 corresponding to the substrate holders 114a, 114b are arranged under and connected to the corresponding substrate holders 114a, 114b by corresponding shafts 154. The linear/rotary actuators 152 move the substrate holders 114a, 114b vertically between the reactor chambers 112a, 112b and the loading area 116, through corresponding loading openings 156 between the loading and process areas 106, 116. For example, during loading or unloading of a substrate holder 114a, 114b, the corresponding linear/rotary actuator 152 moves the substrate holder 114a, 114b vertically down into the loading area 116. As another example, during the semiconductor manufacturing process, the linear/rotary actuators 152 move the substrate holders 114a, 114b vertically up into the reactor chambers 112a, 112b. Further, in some embodiments, the linear/rotary actuators 152 rotate the substrate holders 114a, 114b during the semiconductor manufacturing process to improve the uniformity of the semiconductor manufacturing process across the substrate holders 114a, 114b.

Seal plates 158 corresponding to the substrate holders 114a, 114b are arranged under the corresponding substrate holders 114a, 114b and are configured to seal the loading openings 156 when the substrate holders 114a, 114b are in the reactor chambers 112a, 112b. In some embodiments, the seal plates 158 are mounted to the shafts 154, proximate to the substrate holders 114a, 114b, and move vertically, but not rotationally, with the substrate holders 114a, 114b. In such embodiments, the seal plates 158 may have footprints sized to plug the loading openings 156 or to otherwise fully cover the loading openings 156 when the substrate holders are within the reactor chambers 112a, 112b.

Gas inlets 160 and exhaust outlets 162 corresponding to the reactors 104a, 104b are arranged on opposing sides of the reactor chambers 112a, 112b. The gas inlets 160 receive gases used by the semiconductor manufacturing process from one or more gas sources 164 through corresponding gas inlet lines 166, typically individual to the reactors 104a, 104b. In some embodiments, valves 168 corresponding to the gas inlet lines 166 are arranged along the gas inlet lines 166 to control the flow (e.g., flow rate) of the gases to the gas inlets 160. The valves 168 and/or the gas inlet lines 166 advantageously allow the flow of the gases to the gas inlets 160 to be individually controlled for the reactors 104, 104b. Within the reactor chambers 112a, 112b, gas distribution lines 170 extend from the gas inlets 160, vertically along substantial heights of the substrate stacks, to introduce the gases into the reactor chambers 112a, 112b through nozzles 172 vertically spaced along the gas distribution lines 170. The exhaust outlets 162 provide exhaust gases to corresponding exhaust pumps 174 through corresponding exhaust outlet lines 176.

In some embodiments, one or more sensors 178 are arranged in the reactor chambers 112a, 112b and/or around the reactor chambers 112a, 112b to measure parameters of the semiconductor manufacturing process. Such parameters may include, for example, temperatures, gas concentrations, gas flow rates, and so on. The measurements of the sensor(s) 178 may, in turn, be used as feedback to the control unit 130 (e.g., the process module 134) to better control the individual reactors 104a, 104b to achieve target values for the parameters of the semiconductor manufacturing process.

For example, supposing the semiconductor manufacturing process calls for a target temperature of 200 degrees Fahrenheit in the reactors chambers 112a, 112b, the control unit 130 may initially control the first and second heaters 142, 146 (e.g., for each of the reactors 104a, 104b, apply a respective voltage across the first and second heaters 142, 146 of the reactor 104a, 104b) to achieve the target temperature. Thereafter, the sensor(s) 178 may be used to measure the actual temperatures in the reactor chambers 112a, 112b and, based on the measurements, the control unit 130 may refine its control over the first and second heaters 142, 146 (e.g., for each of the reactors 104a, 104b, increase or decrease the respective voltage across the first and second heaters 142, 146 of the reactor 104a, 104b) to better achieve the target temperature.

The robot 120 is arranged in the loading area 116, under and laterally adjacent to the reactors 104a, 104b. In some embodiments, the robot 120 includes a plurality of vertically stacked blades 126a, 126b respectively including one or more pairs of laterally spaced fingers, each pair typically configured to support a single substrate. Advantageously, such a configuration allows loading or unloading of the reactors 104a, 104b more quickly, thereby improving throughput and WPH.

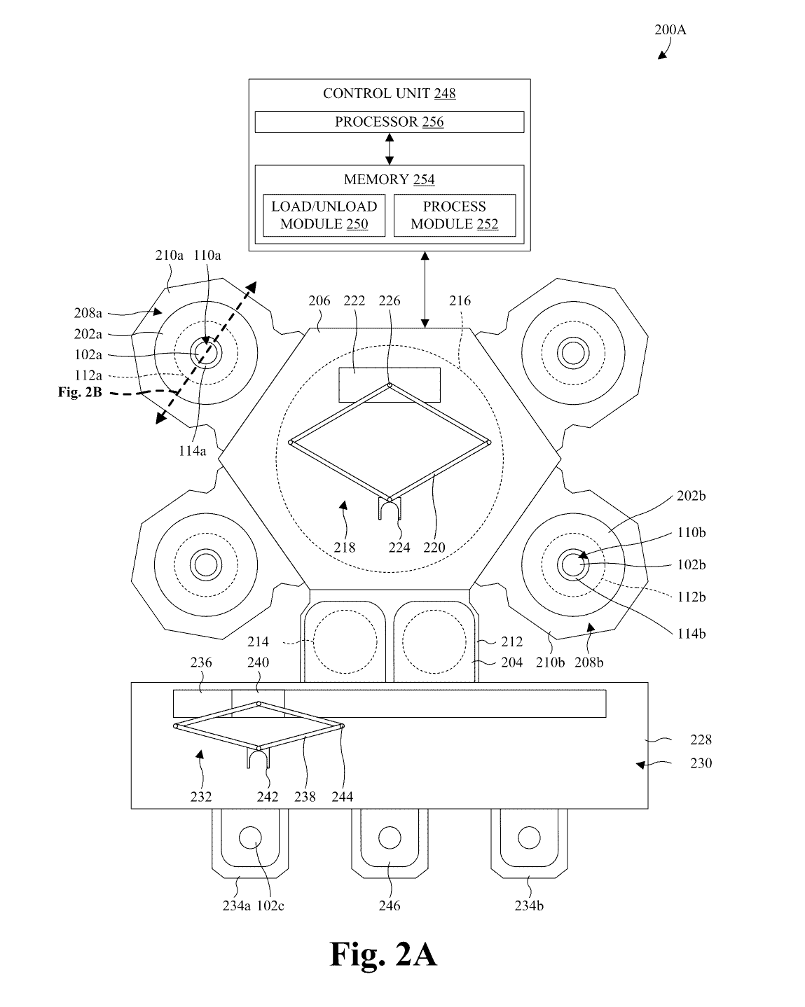

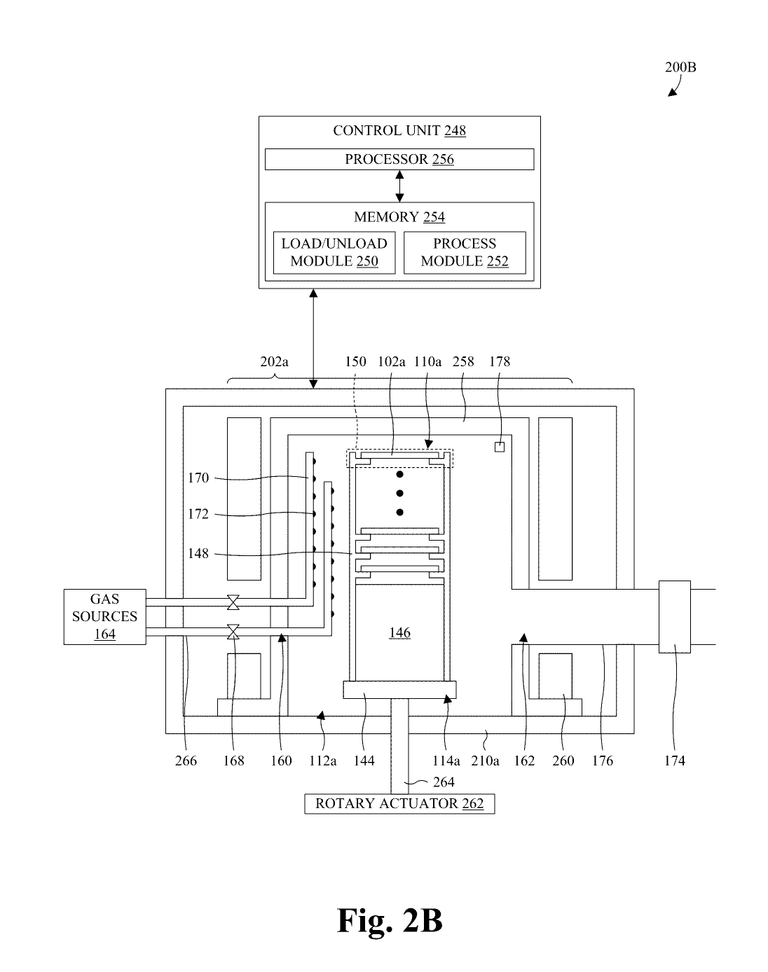

With reference to FIG. 2A, a top view 200A of other embodiments of the multi-chamber furnace is provided. The multi-chamber furnace is configured to process a batch of substrates 102a-c according to a semiconductor manufacturing process dependent upon the application of heat to the substrates 102a-c, such as thermal oxidation and annealing. The batch typically includes about 100 or more substrates 102a-c. The multi-chamber furnace includes a plurality of reactors 202a, 202b and one or more load locks 204 laterally spaced around and abutting a main frame 206. In some embodiments, the multi-chamber furnace includes between about 2 and 4 reactors (illustrated as 4 reactors), and/or about 1 or 2 load locks (illustrated as 2 load locks).

The reactors 202a, 202b are laterally spaced from one another and arranged within corresponding process areas 208a, 208b defined by corresponding process housings 210a, 210b. Further, the reactors 202a, 202b are mounted to facets of the main frame 206 through the process housings 210a, 210b. The reactors 202a, 202b are configured to process corresponding subsets 110a, 110b of the batch (i.e., smaller batches of substrates 102a-c) according to the semiconductor manufacturing process so as to collectively process the whole of the batch. In some embodiments, the reactors 104a, 104b are individually configured to process between about 25 to about 50 substrates 102a, 102b of the batch. Distributing and processing the batch of substrates 102a-c amongst the plurality of reactors 202a, 202b advantageously improves cycle time and uniformity of the semiconductor manufacturing process. The reactors 202a, 202b include corresponding reactor chambers 112a, 112b and corresponding substrate holders 114a, 114b. The reactor chambers 112a, 112b are configured to provide a suitable environment for carrying the semiconductor manufacturing process, and the substrate holders 114a, 114b are configured to vertically stack and space the substrates 102a-c of the corresponding reactors 202a, 202b.

The load lock(s) 204 are arranged in a load lock housing 212, abutting and mounted to a facet of the main frame 206. The load lock(s) 204 include one or more corresponding load lock chambers 214 configured to pass substrates 102a-c between environments on opposing sides of the load lock(s) 204, while maintaining isolation between the environments. In some embodiments, the load lock chamber(s) 214 are individually sized to accommodate the same number of substrates as the reactors 202a, 202b. For example, where the reactors 202a, 202b are sized to accommodate between about 25 to about 50 substrates, the load lock chamber(s) 214 may be individually sized to accommodate between about 25 to about 50 substrates.

The main frame 206 includes a transfer chamber 216 central to the reactors 202a, 202b and the load lock(s) 204. The transfer chamber 216 accommodates a transfer robot 218 configured to place the substrates 102a-c in the reactors 202a, 202b and the load lock(s) 204, and to pick the substrates 102a-c from the reactors 202a, 202b and the load lock(s) 204, so as to facilitate loading and unloading of the batch. During loading of the batch, the substrates 102a-c are moved from the load lock(s) 204 to the respective reactors 202a, 202b. Further, during unloading of the batch, the substrates 102a-c are moved from the respective reactors 202a, 202b to the load lock(s) 204. Although not visible, the main frame 206 has openings that are laterally aligned with corresponding openings in the reactors 202a, 202b and the load lock(s) 204 to allow the transfer robot 218 to access the reactors 202a, 202b during loading and unloading. When loading and unloading are complete, doors (not shown) seal the openings.

The transfer robot 218 includes one or more rods 220 connected end to end between a motor 222 and a vertical stack of one or more blades 224 by bearings 226. The motor 222 is configured to vertically, horizontally, and/or rotationally move the blade(s) 224 along the bearings 226. The blade(s) 224 respectively include one or more pairs of laterally spaced fingers, each pair typically configured to support a single substrate. In some embodiments, the blade(s) 224 are limited to a single blade configured to support a single substrate. In other embodiments, the blade(s) 224 include multiple blades, each comprising one or more pairs of laterally spaced fingers configured to support at least one substrate. In yet other embodiments, the blade(s) 224 include a single blade comprising multiple pairs of laterally spaced fingers configured to support a plurality of substrates. For example, the blade(s) 224 may include between about 25 to about 50 vertically stacked blades and/or pairs of laterally spaced fingers to concurrently transfer all of the substrates 102a-c of a reactor 202a, 202b.

In some embodiments, a loading housing 228 abuts the load lock(s) 204, opposite the main frame 206. The loading housing 228 defines a loading area 230 accommodating a loading robot 232 configured to transfer substrates 102a-c between the load lock(s) 204 and a plurality of pod loaders 234a, 234b, such as between about 2 and about 4 pod loaders (illustrated as 3 pod loaders). The loading robot 232 is typically arranged on a track 236 to move within the loading area 230. The loading robot 232 includes one or more rods 238 connected end to end between a motor 240 and a vertical stack of one or more blades 242 by bearings 244. The motor 240 is configured to vertically, horizontally, and/or rotationally move the blade(s) 242 along the bearings 244. The blade(s) 242 respectively include one or more pairs of laterally spaced fingers, each pair typically configured to support a single substrate. For example, the blade(s) 242 may be configured to concurrently carry about 5 substrates.

The pod loaders 234a, 234b are configured to support pods 246 (e.g., FOUPs) for transporting the substrates 102a-c between processing systems, and are typically arranged on an opposite side of the loading housing 228 as the load lock(s) 204. In some embodiment, the pods 246 correspond to the reactors 202a, 202b with a one-to-one or a many-to-one correspondence. In some of such embodiments, the pods 246 individually accommodate the same number of substrates as the corresponding reactors 202a, 202b or a fraction (e.g., ½ or ¼) of the number of substrates accommodated by the corresponding reactors 202a, 202b. The pods 246 advantageously expedite the loading of the reactors 202a, 202b and ease the transport of the substrates 102a-c.

A control unit 248 is electrically coupled with the reactors 202a, 202b, the load lock(s) 204, and/or the robots 218, 232, and configured to control the reactors 202a, 202b, the load lock(s) 204, and/or the robots 218, 232. For example, the control unit 248 may include a load/unload module 250 configured to control the transfer and/or loading robots 218, 232, the load lock(s) 204, and/or the reactors 202a, 202b for the loading and unloading of substrates 102a-c to and from the substrate holders 114a, 114b. As another example, the control unit 248 may include a process module 252 configured to individually control the reactors 202a, 202b to carry out the semiconductor manufacturing process on the substrates 102a-c. The control unit 248 is implemented by hardware and, in some embodiments, software configured to carry out the foregoing functionality. To the extent that the control unit 248 includes software, the control unit 248 includes at least one memory 254 storing the software and at least one processor 256 configured to execute the software.

With reference to FIG. 2B, a cross-sectional view 200B of some embodiments of the multi-chamber furnace is provided. The reactors 202a, 202b include corresponding reactor housings 258 defining the reactor chambers 112a, 112b, and include corresponding first heaters 260 surrounding the reactor chambers 112a, 112b outside the reactor chambers 112a, 112b. The first heaters 260 may be, for example, resistive heaters.

The substrate holders 114a, 114b include corresponding bases 144 supporting corresponding second heaters 146 and corresponding racks 148. The racks 148 include corresponding vertical stacks of slots 150 for the substrates 102a-c, such as one slot for each substrate. While the slots 150 are typically fixed, in some embodiments, the slots 150 may be removable or otherwise moveable within the reactor chambers 112a, 112b. For example, the slots 150 may be loaded and unloaded with the substrates 102a-c, and/or all substrates 102a-c of a reactor chamber 112a, 112b may be moved between the load lock(s) 204 (see FIG. 2A) and the reactor chamber 112a, 112b with the corresponding slots 150. In some embodiments, the substrate holders 114a, 114b are arranged over and connected to corresponding rotary actuators 262 by corresponding shafts 264. The rotary actuators 262 rotate the substrate holders 114a, 114b during the semiconductor manufacturing process to improve the uniformity of the semiconductor manufacturing process.

Exhaust outlets 162 corresponding to the reactors 104a, 104b provide gases from the reactors chambers 112a, 112b to corresponding exhaust pumps 174 through corresponding exhaust outlet lines 176. Further, gas inlets 160 corresponding to the reactors 104a, 104b receive gases used by the semiconductor manufacturing process from one or more gas sources 164 through corresponding gas inlet lines 266, typically individual to the reactors 104a, 104b. In some embodiments, valves 168 corresponding to the gas inlet lines 266 are arranged along the gas inlet lines 266 to control the flow (e.g., flow rate) of the gases to the gas inlets 160. The valves 168 and/or the gas inlet lines 266 advantageously allow the flow of the gases to the gas inlets 160 to be individually controlled for the reactors 104, 104b. Within the reactor chambers 112a, 112b, gas distribution lines 170 and corresponding nozzles 172 extend from the gas inlets 160 to introduce the gases into the reactor chambers 112a, 112b.

In some embodiments, one or more sensors 178 are arranged in the reactor chambers 112a, 112b and/or around the reactor chambers 112a, 112b to measure parameters of the semiconductor manufacturing process. The measurements of the sensor(s) 178 may, in turn, be used as feedback to the control unit 248 (e.g., the process module 252) to better control the individual reactors 202a, 202b to achieve target values for parameters of the semiconductor manufacturing process.

While the reactors 104a, 104b are described above in FIGS. 1A & B and FIGS. 2A & B as performing the same semiconductor manufacturing process, it is to be appreciated that, in some embodiments, the reactors 104a, 104b may also perform different semiconductor manufacturing processes. For example, the reactors 104a, 104b may correspondingly perform polysilicon, oxide, and nitride semiconductor manufacturing processes, such as deposition processes. In such embodiments, the gases flowing to the reactors 104a, 104b and/or other parameters of the reactors 104, 104b may be individually controlled in accordance with the respective semiconductor manufacturing processes.

Further, in some embodiments, the semiconductor manufacturing process in FIGS. 1A & B and FIGS. 2A & B may be an atomic layer deposition (ALD) of silicon nitride or oxide. For ALD of silicon nitride, the semiconductor manufacturing process may, for example, be performed: at a temperature of about 200-600 degrees Celsius; at a pressure between a few millitorrs to a few torrs; with a process gas comprising silane (SiH₄) and/or ammonia (NH₃), and a flow rate between a few standard cubic centimeters per minute (SCCMs) to a few standard liters per minute (SLMs); and for a time between a few minutes to a few hours. For ALD of oxide, the semiconductor manufacturing process may, for example, be performed: at a temperature of about 20-500 degrees Celsius; at a pressure between a few millitorrs to a few torrs; with a process gas comprising SiH₄ and/or tetraethyl orthosilicate (TEOS), and a flow rate between a few SCCMs to a few SLMs; and for a time between a few minutes to a few hours.

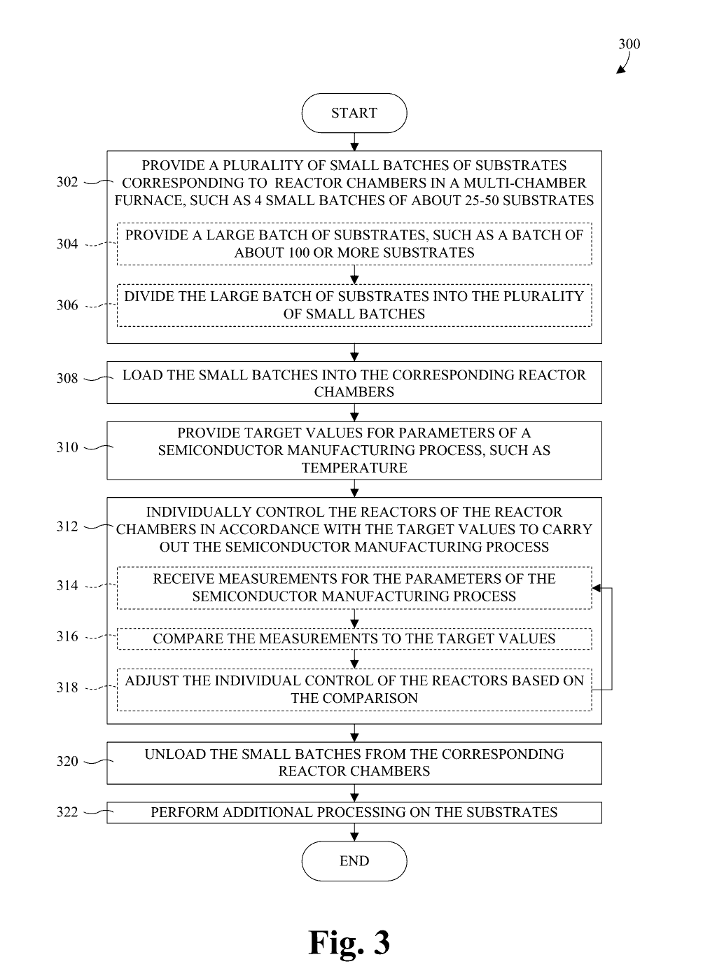

With reference to FIG. 3, a flowchart 300 of some embodiments of a method for batch processing substrates, such as wafers, in a multi-chamber furnace is provided. The wafers may be, for example, quartz, silicon carbide, or ceramic. The substrates are processed according to a semiconductor manufacturing process dependent upon the application of heat to the substrates, such as thermal oxidation and annealing. In some embodiments, the multi-chamber furnace corresponds to the embodiments of FIGS. 1A & B or the embodiments of FIGS. 2A & B.

At 302, a plurality of small batches of substrates (e.g., batches of about 25-50 substrates) corresponding to reactor chambers in the multi-chamber furnace is provided. For example, supposing the multi-chamber furnace has 4 reactor chambers, 4 small batches may be provided. In some embodiments, providing the plurality of small batches includes Acts 304 and 306. At 304, a large batch of substrates (e.g., a batch of 100 more substrates) is provided. At 306, the large batch of substrates is divided into the plurality of small batches. The substrates are typically semiconductor wafers, such as 300 or 450 millimeter semiconductor wafers. The semiconductor wafers may be, for example, quartz, silicon carbide, or ceramic.

At 308, the small batches are loaded into the corresponding reactor chambers of the multi-chamber furnace. This may entail controlling reactors of the reactor chambers and/or one or more robots of the multi-chamber furnace to move the substrates of the small batches into the reactor chambers.

At 310, target values for parameters of the semiconductor manufacturing process are provided. Such parameters may include, for example, temperatures, gas flow rates, gas concentrations, and so on.

At 312, the reactors of the reactor chambers are individually controlled in accordance with the target values to carry out the semiconductor manufacturing process on the small batches. By performing the semiconductor manufacturing process concurrently on a plurality of small batches, as opposed to on a single large batch, cycle time can advantageously be reduced and the WPH can be increased. Further, the parameters of the semiconductor manufacturing process can advantageously be controlled more readily across the substrates. This, in turn, may advantageously improve the WiB uniformity of the semiconductor manufacturing process. For example, for a thermal oxidation semiconductor manufacturing process, the uniformity of the WiB thickness profiles of the deposited layers may be improved and/or the WiB percentage of non-uniform substrates may be reduced.

In some embodiments, the individual control of the reactors includes Acts 314, 316, 318. These Acts 314, 316, 318 may be repeated continuously or periodically throughout the semiconductor manufacturing process. Such feedback-based control advantageously helps improve the uniformity of the semiconductor manufacturing process across the substrates.

At 314, measurements for the parameters of the semiconductor manufacturing process are received from one or more sensors arranged around and/or within the reactor chambers. For example, temperature sensors may be placed throughout the reactor chambers to measure the temperatures of the reactor chambers during the semiconductor manufacturing process. As another example, gas sensors may be placed throughout the reactor chambers to measure the concentrations of process gases within the reactor chambers during the semiconductor manufacturing process.

At 316, the measurements are compared against the target values to determine discrepancies between the measurements and the target values.

At 318, control over the reactors is adjusted to minimize the discrepancies between the measurements and the target values. For example, if measurements for a reactor indicate that its internal temperature is about 5 degrees Fahrenheit above a corresponding target value, heaters of the reactor may be adjusted to reduce the discrepancy.

At 320, the small batches are unloaded from the corresponding reactor chambers of the multi-chamber furnace. This may entail controlling the reactors of the reactor chambers and/or the robot(s) of the multi-chamber furnace to move the substrates out of the corresponding reactor chambers.

At 322, additional processing of the substrates is performed.

While the plurality of small batches of substrates are described above as being processed according to a common semiconductor process, it is to be appreciated that, in some embodiments, the plurality of small batches of substrates may also be individually processed according to different semiconductor manufacturing processes. For example, the plurality of small batches of substrates may correspondingly be processed according polysilicon, oxide, and nitride semiconductor manufacturing processes. In such embodiments, parameters of the reactors, such as gas types and/or temperatures, may be individually controlled in accordance with the respective semiconductor manufacturing processes.

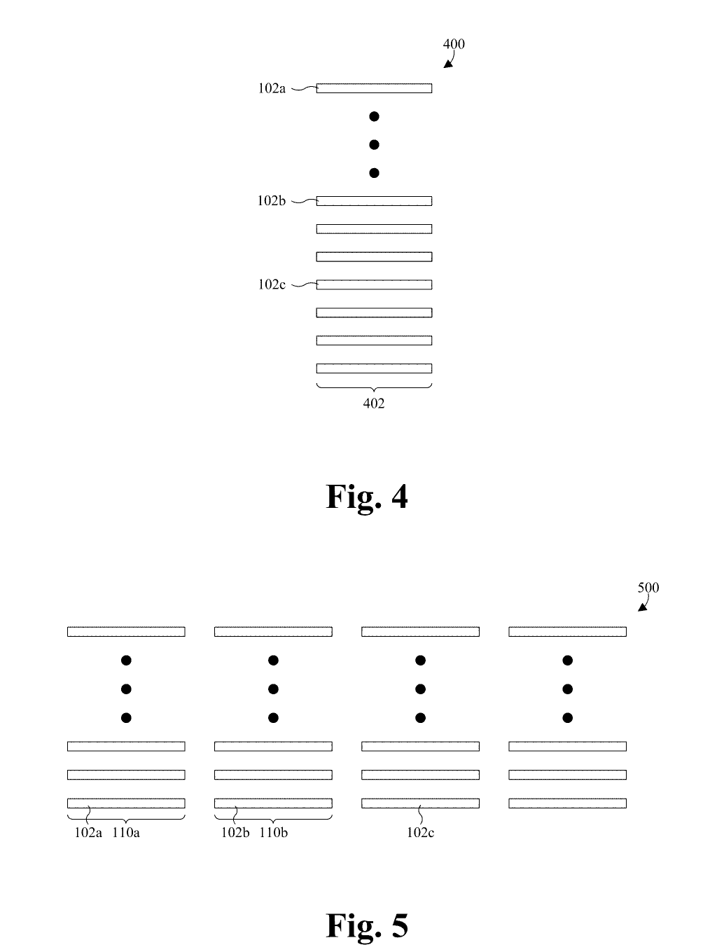

With reference to FIGS. 4, 5, 6A-E, and 7A-E, graphical illustrations of some embodiments of the acts of the method of FIG. 3 are provided. Although FIGS. 4, 5, 6A-E, and 7A-E are described in relation to the method, it will be appreciated that FIGS. 4, 5, 6A-E, and 7A-E are not limited to the method, but instead may stand alone. Similarly, although the method is described in relation to FIGS. 4, 5, 6A-E, and 7A-E, it will be appreciated that the method is not limited to the FIGS. 4, 5, 6A-E, and 7A-E, but instead may stand alone.

FIGS. 4 and 5 are cross-sectional views 400, 500 of some embodiments corresponding to Acts 302, 304, 306.

As illustrated by FIG. 4, a large batch 402 of substrates 102a-c is provided. The large batch 402 typically includes about 100 or more substrates.

As illustrated by FIG. 5, the large batch 402 of substrates 102a-c (see FIG. 4) is divided into a plurality of small batches 110a, 110b corresponding to reactor chambers of a multi-chamber furnace. The small batches 110a, 110b typically share a common size. Further, each of the small batches 110a, 110b typically includes between about 25-50 substrates, and no more than about 50 substrates.

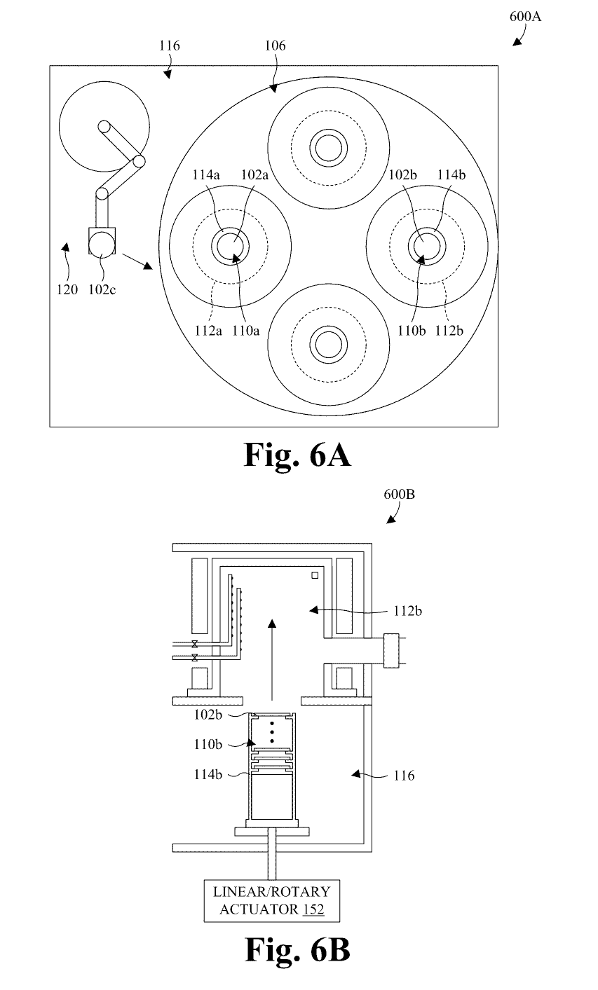

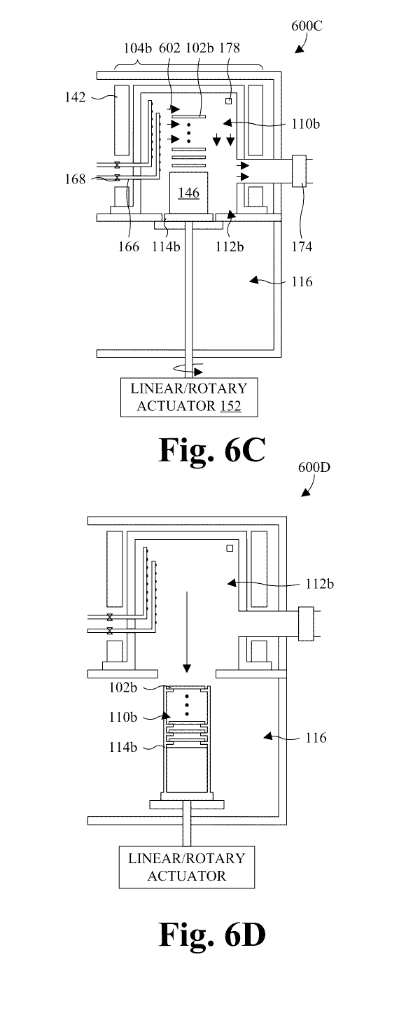

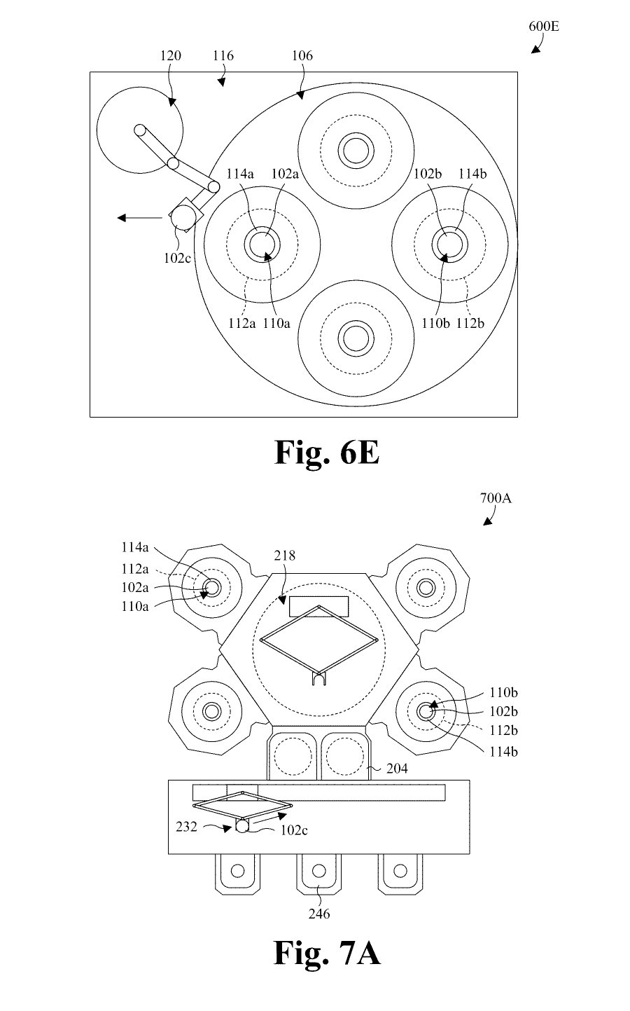

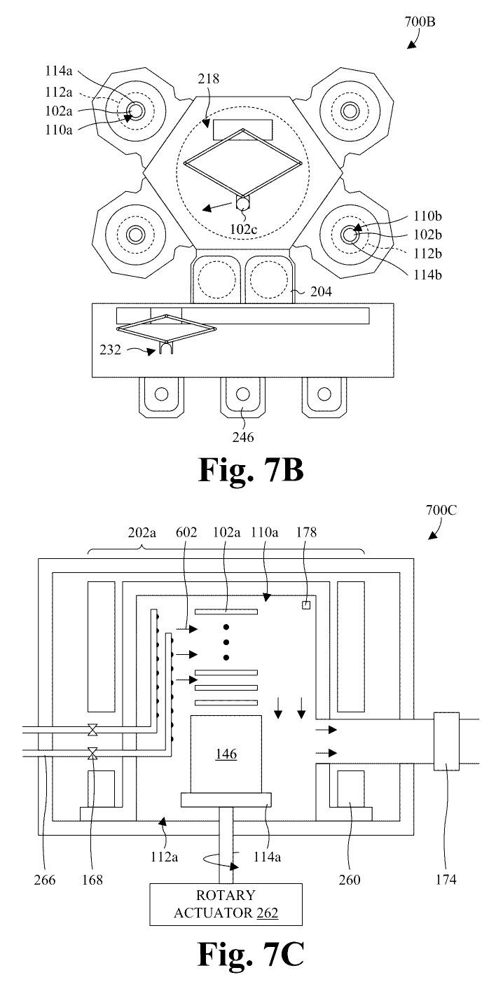

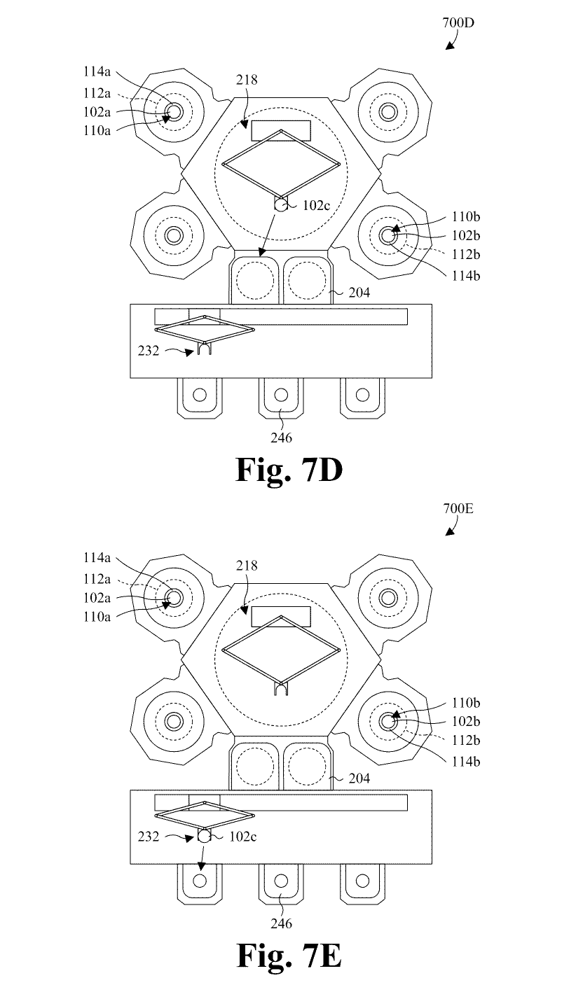

FIGS. 6A-E are top and cross-sectional views 600A-E of some embodiments corresponding to Acts 308, 312, 320. These embodiments are directed towards the multi-zone chamber described above in FIGS. 1A & B.

As illustrated by FIG. 6A, a robot 120 loads the substrates 102a-c of the small batches 110a, 110b into substrate holders 114a, 114b of corresponding reactor chambers 112a, 112b. The robot 120 loads the substrates 102a-c into the substrate holders 114a, 114b in a loading area 116 arranged under a process area 106 accommodating the reactor chambers 112a, 112b. In some embodiments, the robot 120 loads the substrates 102a-c into the substrate holders 114a, 114b from pods (e.g., FOUPs) corresponding to the substrate holders 114a, 114b with a one-to-one or a many-to-one correspondence. In some of such embodiments, the pods individually accommodate the same number of substrates as the corresponding substrate holders 114a, 114b or a fraction of the number of substrates accommodated by the corresponding substrate holders 114a, 114b.

As illustrated by FIG. 6B, the substrate holders 114a, 114b (see FIG. 6A) are moved up from the loading area 116 into the reactor chambers 112a, 112b (see FIG. 6A) after loading by the robot 120. Typically, the substrate holders 114a, 114b are moved with linear/rotary actuators 152 arranged under the substrate holders 114a, 114b.

As illustrated by FIG. 6C, a semiconductor manufacturing process is performed on the substrates 102a-c (see FIG. 6A) through individual control over reactors 104b of the reactor chambers 112a, 112b (see FIG. 6A). In some embodiments, the individual control includes the application of heat and/or process gases 602 to the substrates 102a-c. For example, the heat may be applied with heaters 142, 146 surrounding the substrates 102a-c. As another example, the process gases 602 may be applied through control of valves 168 along gas inlet lines 166 connecting the reactor chambers 112a, 112b to gas sources, and/or through control of exhaust pumps 174 connected to the reactor chambers 112a, 112b. Further, in some embodiments, the individual control includes rotating the substrate holders 114a, 114b (see FIG. 6A) and/or is based on feedback from sensors 178 arranged around and/or within the reactor chambers 112a, 112b. Typically, the substrate holders 114a, 114b are rotated with the linear/rotary actuators 152.

As illustrated by FIG. 6D, the substrate holders 114a, 114b (see FIG. 6A) are moved down into the loading area 116 after performing the semiconductor manufacturing process. Typically, the substrate holders 114a, 114b are moved with the linear/rotary actuators 152.

As illustrated by FIG. 6E, the robot 120 unloads the substrates 102a-c from the substrate holders 114a, 114b in the loading area 116.

FIGS. 7A-E are top and cross-sectional views 700A-E of some embodiments corresponding to Acts 308, 312, 320. These embodiments are directed towards the multi-zone chamber described above in FIGS. 2A & B.

As illustrated by FIG. 7A, a loading robot 232 moves the substrates 102a-c of the small batches 110a, 110b from pods 248 (e.g., FOUPs) to one or more load locks 204. In some embodiments, the pods 248 correspond to reactor chambers 112a, 112b to which the substrates 102a-c are being moved with a one-to-one or a many-to-one correspondence. In some of such embodiments, the pods 248 individually accommodate the same number of substrates as the corresponding reactor chambers 112a, 112b or a fraction of the number of substrates accommodated by the corresponding reactor chambers 112a, 112b. Further, in some embodiments, the loading robot 232 moves multiple substrates (e.g., about 5 substrates or about 25-50 substrates) at a time.

As illustrated by FIG. 7B, a transfer robot 218 moves the substrates 102a-c of the small batches 110a, 110b from the load lock(s) 204 to substrate holders 114a, 114b of corresponding reactor chambers 112a, 112b. In some embodiments, the transfer robot 218 moves multiple substrates (e.g., about 5 substrates or about 25-50 substrates) at a time.

It is to be appreciated that the acts of FIGS. 7A & B may be performed iteratively due to limitations on the load lock size. For example, the load lock(s) 204 may not be able to concurrently accommodate all the substrates 102a-c of the small batches 110a, 110b. Therefore, the load lock(s) 204 may be fully loaded by the loading robot 232, and subsequently emptied by the transfer robot 218, multiple times. As another example, where the load lock(s) 204 are configured to accommodate the same number of substrates as the reactor chambers 112a, 112b (e.g., between about 25-50 substrates), each of the small batches 110a, 110b may be fully loaded into a load lock 204 by the loading robot 232, and subsequently transferred out of the load lock 204 by the transfer robot 218.

As illustrated by FIG. 7C, a semiconductor manufacturing process is performed on the substrates 102a-c (see FIGS. 7A & B) through individual control over reactors 202a of the reactor chambers 112a, 112b (see FIGS. 7A & B). In some embodiments, the individual control includes the application of heat and/or process gases 602 to the substrates 102a-c. For example, the heat may be applied with heaters 146, 260 surrounding the substrates 102a-c. As another example, the process gases 602 may be applied through control of valves 168 along gas inlet lines 266 connecting the reactor chambers 112a, 112b to gas sources, and/or through control of exhaust pumps 174 connected to the reactor chambers 112a, 112b. Further, in some embodiments, the individual control includes rotating the substrate holders 114a, 114b (see FIGS. 7A & B) and/or is based on feedback from sensors 178 arranged around and/or within the reactor chambers 112a, 112b. Typically, the substrate holders 114a, 114b are rotated with rotary actuators 262.

As illustrated by FIG. 7D, the transfer robot 218 moves the substrates 102a-c of the small batches 110a, 110b from the substrate holders 114a, 114b to the load lock(s) 204. In some embodiments, the transfer robot 218 moves multiple substrates (e.g., about 5 substrates or about 25-50 substrates) at a time.

As illustrated by FIG. 7E, the loading robot 232 moves the substrates 102a-c of the small batches 110a, 110b from the load lock(s) 204 to the pod loaders 234a, 234b. In some embodiments, the loading robot 232 moves multiple substrates (e.g., about 5 substrates or about 25-50 substrates) at a time.

As with the acts of FIGS. 7A & B, it is to be appreciated that the acts of FIGS. 7D & E may be performed iteratively due to limitations on the load lock size. For example, where the load lock(s) 204 are configured to accommodate the same number of substrates as the reactor chambers 112a, 112b (e.g., between about 25-50 substrates), each of the small batches 110a, 110b may be fully loaded into a load lock 204 by the transfer robot 218, and subsequently transferred out of the load lock 204 by the loading robot 232.

Thus, as can be appreciated from above, the present disclosure is directed towards a technique for improving process uniformity by dividing a large process chamber into a plurality of smaller process chambers, typically individually accommodating between about 25-50 substrates. While the technique of improving process uniformity is used for furnace applications, it is to be appreciated that it can be used for other applications. For example, the technique of improving process uniformity may be used with chemical vapor deposition (CVD), atomic layer deposition (ALD), physical vapor deposition (PVD), and so on.

In some embodiments, the present disclosure provides a multi-chamber furnace. Reactor housings define a plurality of laterally spaced reactor chambers that are individually configured to accommodate up to about 50 substrates. Substrate holders correspond to the reactor chambers are configured to support and vertically stack substrates arranged in the corresponding reactor chambers. Heaters correspond to the reactor chambers and are configured to heat the corresponding reactor chambers.

In other embodiments, the present disclosure provides a method for batch processing substrates in a multi-chamber furnace. A plurality of substrate batches corresponding to reactor chambers of a multi-chamber furnace is provided. The substrate batches individually include up to about 50 substrates. The substrate batches are transferred to the corresponding reactor chambers of the multi-chamber furnace. A semiconductor manufacturing process is concurrently performed on the substrate batches using the multi-chamber furnace. The substrate batches are transferred out of the corresponding reactor chambers of the multi-chamber furnace.

In yet other embodiments, the present disclosure provides a multi-chamber furnace. Reactor housings define a plurality of laterally spaced reactor chambers that are individually configured to accommodate between about 25 substrates and about 50 substrates. Substrate holders correspond to the reactor chambers, and are configured to support and vertically stack substrates arranged in the corresponding reactor chambers. The substrate holders respectively include vertical stacks of slots configured to accommodate individual substrates. First heaters correspond to the reactor chambers and laterally surround the corresponding reactor chambers. Second heaters correspond to the reactor chambers and are arranged under the slots.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A multi-chamber furnace comprising:
reactor housings defining a plurality of laterally spaced reactor chambers that are individually configured to accommodate a number of substrates that is about equal to an integer multiple of a number of substrates held by a pod configured to transport substrates;
substrate holders corresponding to the reactor chambers, and configured to support and stack substrates arranged in the corresponding reactor chambers; and
heaters corresponding to the reactor chambers and configured to heat the corresponding reactor chambers.

2. The multi-chamber furnace according to claim 1, wherein the reactor chambers are collectively configured to concurrently carry out a semiconductor manufacturing process on a batch of about 100 or more substrates.

3. The multi-chamber furnace according to claim 1, wherein the reactor chambers are configured to carry out different semiconductor manufacturing processes on substrates.

4. The multi-chamber furnace according to claim 1, wherein the reactor chambers individually accommodate between about 25 substrates and about 50 substrates.

5. The multi-chamber furnace according to claim 1, further comprising:
a process housing defining a process area within which the reactor housings are arranged; and
a loading housing defining a loading area under the process area.

6. The multi-chamber furnace according to claim 5, further comprising:
a linear actuator configured to move the substrate holders between the reactor chambers and the loading area.

7. The multi-chamber furnace according to claim 1, further comprising:
a main frame defining a transfer chamber, wherein the reactor chambers are laterally spaced around the main frame; and
a transfer robot arranged in the transfer chamber and configured to move substrates in and out of the reactor chambers.

8. The multi-chamber furnace according to claim 7, further comprising:
a load lock housing defining a load lock chamber and arranged adjacent to the main frame, wherein the transfer robot is further configured to move substrates between the load lock chamber and the plurality of reactor chambers.

9. The multi-chamber furnace according to claim 8, wherein the load lock chamber is configured to accommodate between about 25 substrates and about 50 substrates.

10. The multi-chamber furnace according to claim 1, further comprising:
a robot configured to concurrently move multiple substrates in or out of the reactor chambers.

11. A method for batch processing substrates in a multi-chamber furnace, the method comprising:
providing a plurality of pods holding a plurality of substrate batches, wherein the substrate batches correspond to reactor chambers of a multi-chamber furnace, and wherein the reactor chambers individually accommodate a number of substrates that is about equal to an integer multiple of a number of substrates held by one of the pods;
transferring the substrate batches to the corresponding reactor chambers of the multi-chamber furnace;
performing a semiconductor manufacturing process on the substrate batches using the multi-chamber furnace; and
transferring the substrate batches out of the corresponding reactor chambers of the multi-chamber furnace.

12. The method according to claim 11, wherein the plurality of substrate batches collectively comprise at least about 100 substrates.

13. The method according to claim 11, wherein the plurality of substrate batches individually comprise between about 25 to about 50 substrates.

14. The method according to claim 11, wherein providing the plurality of substrate batches comprises:
providing a large batch of about 100 or more substrates that is larger than any one of the plurality of substrate batches; and
dividing the large batch into the plurality of substrates.

15. The method according to claim 11, further comprising:
performing thermal oxidation or annealing on the substrate batches using the multi-chamber furnace.

16. The method according to claim 11, wherein performing the semiconductor manufacturing process comprises:
individually controlling reactors of the reactor chambers in accordance feedback from sensors of the reactors.

17. The method according to claim 11, wherein transferring the substrate batches to the corresponding reactor chambers comprises:
lowering substrate holders of the reactor chambers into a loading area under the reactor chambers;
moving the substrate batches to the substrate holders of the corresponding reactor chambers in the loading area; and
raising the substrate holders of the reactor chambers into the reactor chambers.

18. The method according to claim 11, wherein transferring the substrate batches to the corresponding reactor chambers comprises:
moving the substrate batches from one or more load lock chambers, laterally through a transfer chamber, to the corresponding reactor chambers, wherein the reactor chambers and the one or more load lock chambers are laterally spaced around the transfer chamber.

19. The method according to claim 18, wherein transferring the substrate batches to the corresponding reactor chambers comprises:
moving all substrates of a substrate batch from a load lock chamber, laterally through the transfer chamber, to a corresponding reactor chamber, wherein the substrate batch comprises between about 25-50 substrates.

20. A multi-chamber furnace comprising:
reactor housings defining a plurality of laterally spaced reactor chambers that are individually configured to accommodate between about 25 substrates and about 50 substrates;
substrate holders corresponding to the reactor chambers that are configured to support and stack substrates arranged in the corresponding reactor chambers, wherein the substrate holders respectively include stacks of slots configured to accommodate individual substrates;
first heaters corresponding to the reactor chambers and laterally surrounding the corresponding reactor chambers; and
second heaters corresponding to the reactor chambers and arranged under the slots.
